(19) United States
(12) Patent Application Publication
(10) Pub. No.: US 2019/0382882 A1
(43) Pub. Date: Dec. 19, 2019

(54) VACUUM DEPOSITION PROCESSING OF MULTIPLE SUBSTRATES

(71) Applicant: X Development LLC, Mountain View, CA (US)

(72) Inventors: Michael Jason Grundmann, San Jose, CA (US); Sylvia Joan Smullin, Menlo Park, CA (US); James Lubin, Oakland, CA (US)

(21) Appl. No.: 16/007,582

(22) Filed: Jun. 13, 2018

(51) Int. Cl. C23C 14/50; C23C 14/34; C23C 16/458; C23C 14/58; C23C 14/02; C23C 16/02; C23C 16/56; C23C 16/52

(52) U.S. Cl. CPC C23C 14/505; C23C 14/34; C23C 16/4584; C23C 14/5806; C30B 23/02; C23C 16/0209; C23C 16/56; C23C 16/52; C23C 14/02

(57) ABSTRACT

A vacuum deposition system includes a vacuum deposition chamber having multiple regions defined therein; a carousel disposed in the vacuum deposition chamber, the carousel configured to hold multiple substrates, the carousel rotatable around a central spindle; a deposition source positioned to deposit material onto a substrate located in a deposition region of the vacuum deposition chamber; and multiple heating elements disposed in the vacuum deposition chamber in a fixed position relative to the central spindle, each heating element being controllable separately from each other heating element, wherein each heating element is positioned to apply heat to a corresponding region of the vacuum deposition chamber.

### BACKGROUND

To study materials properties or the effect of deposition conditions on a resulting thin film, a large library of samples processed under different conditions can be generated. One approach to generating a library of samples in a vacuum deposition system is gradient deposition, in which materials are deposited in a non-uniform fashion onto a large wafer, thereby resulting in a compositional gradient across the wafer. Another approach to generating a library of samples in a vacuum deposition system is masking, in which a wafer is masked to allow for deposition under certain conditions onto only the unmasked areas of the wafer. The wafer is then masked differently to allow for deposition under different conditions onto other areas of the wafer.

### SUMMARY

In an aspect, a vacuum deposition system includes a vacuum deposition chamber having multiple regions defined therein; a carousel disposed in the vacuum deposition chamber, the carousel configured to hold multiple substrates, the carousel rotatable around a central spindle; a deposition source positioned to deposit material onto a substrate located in a deposition region of the vacuum deposition chamber; and multiple heating elements disposed in the vacuum deposition chamber in a fixed position relative to the central spindle, each heating element being controllable separately from each other heating element, wherein each heating element is positioned to apply heat to a corresponding region of the vacuum deposition chamber.

Embodiments can include one or more of the following features.

The carousel includes multiple substrate carriers each configured to hold a corresponding substrate.

In response to a rotation of the carousel, the substrate carriers are moved from (1) a first position in which each substrate carrier is located in a corresponding first region of the vacuum deposition chamber to (2) a second position in which each substrate carrier is located in a corresponding second region of the vacuum deposition chamber.

At least one of the multiple heating elements is a pre-deposition heating element positioned such that in response to the rotation of the carousel, the substrate carrier in the region corresponding to the pre-deposition heating element is moved to the deposition region.

At least one of the multiple heating elements is a post-deposition heating element positioned such that in response to the rotation of the carousel, the substrate carrier in the deposition region is moved into the region corresponding to the post-deposition heating element.

Each substrate carrier is sized to receive a substrate holder holding the corresponding substrate.

Each substrate holder includes a base with a recess formed therein, the recess being sized to hold the substrate.

Walls defining the recess of each substrate holder are inclined at an angle of less than 90° to a surface of the base.

The multiple heating elements include ceramic heaters.

The multiple heating elements include laser heaters.

The vacuum deposition system includes a control system configured to control each heating element separately from each other heating element.

The control system includes a closed loop control system.

The closed loop control system is configured to control each heating element based on a temperature measured in the corresponding region of the vacuum deposition chamber.

The vacuum deposition system includes multiple pyrometers, each pyrometer configured to measure a temperature of one or more of (1) a substrate, (2) a substrate holder holding a substrate, and (3) a substrate carrier in a corresponding region of the vacuum deposition chamber.

The vacuum deposition system includes an input assembly for automated loading of a substrate into the vacuum deposition chamber.

The input assembly includes an input arm disposed in the vacuum deposition chamber, the input arm configured for vertical movement; and a transfer arm configured for horizontal movement into the vacuum deposition chamber.

The vacuum deposition system includes a physical vapor deposition chamber.

The vacuum deposition chamber includes a chemical vapor deposition chamber.

In an aspect, an apparatus includes a carousel for a vacuum deposition chamber, the carousel having multiple substrate carriers arranged radially around a central spindle, each substrate carrier configured to hold a substrate, wherein the carousel is rotatable around the central spindle; multiple heating elements disposed in the vacuum deposition chamber above the substrate carriers, each heating element being controllable separately from each other heating element, wherein the heating elements are fixed in position relative to the central spindle; an input arm configured to transfer a substrate input into the vacuum deposition chamber onto a substrate carrier, the input arm configured for vertical motion; and an output arm configured to transfer a substrate from a substrate carrier to an output mechanism, the output arm configured for vertical motion.

In an aspect, a method includes holding multiple substrates in a carousel disposed in a vacuum deposition chamber; and rotating the carousel in the vacuum deposition chamber. The rotating includes, for each of the multiple substrates, in a first region of the vacuum deposition chamber, exposing the substrate to a first thermal treatment by a pre-deposition heating element; in a second region of the vacuum deposition chamber, depositing a material from a deposition source onto a surface of the substrate; and in a third region of the vacuum deposition chamber, exposing the substrate to a second thermal treatment by a post-deposition heating element. The method includes controlling one or more of the pre-deposition heating element, the deposition source, and the post-deposition heating element on a per-substrate basis.

Embodiments can include one or more of the following features.

Controlling the pre-deposition heating element or the post-deposition heating element includes adjusting one or more of a maximum power, a minimum power, and a rate of power change.

Controlling the deposition source includes controlling one or more of a deposition rate, a temperature of the deposition source, a power, a bias applied to the substrate, and a deposition time.

Controlling the deposition source includes selecting one or more of multiple deposition sources.

Exposing each substrate to the first thermal treatment includes exposing each substrate to multiple, sequential thermal treatments, each of the sequential thermal treatments by a corresponding one of multiple pre-deposition heating elements.

The method includes controlling each of the multiple pre-deposition heating elements separately from each other of the multiple pre-deposition heating elements.

The method includes controlling one or more of the pre-deposition heating element and the post-deposition heating element by a closed loop control system.

The method includes measuring a temperature in one or more of the first region and the third region of the vacuum deposition chamber.

The method includes one or more of controlling the pre-deposition heating element based on the temperature measured in the first region and controlling the post-deposition heating element based on the temperature measured in the second region.

The method includes measuring one or more of a thickness and a uniformity of the material deposited onto the surface of each substrate.

Depositing a material includes depositing the material by a physical vapor deposition process.

Depositing a material includes depositing the material by a chemical vapor deposition process.

The method includes transferring a substrate from an input cassette elevator to the carousel.

Transferring a substrate from the input cassette elevator to the carousel includes retrieving the substrate from a cassette in the input cassette elevator with a transfer arm; advancing the transfer arm into the vacuum deposition chamber; transferring the substrate from the transfer arm to an input arm disposed in the vacuum deposition chamber; and actuating the input arm to dispose the substrate on the carousel.

Retrieving the substrate from the cassette includes advancing the transfer arm into the cassette in a space below the substrate; and actuating a downward motion of the input cassette elevator to dispose the substrate on the transfer arm.

The method includes transferring a substrate from the carousel to an output cassette elevator.

The approaches described here can have one or more of the following advantages. A large library of samples can be generated quickly and under automatic control. Each sample in the library can have been processed under a unique set of processing conditions. Such a library of samples can be useful, e.g., for testing the effect of processing conditions on material properties, thin film quality or uniformity, or other sample characteristics.

### BRIEF DESCRIPTION OF DRAWINGS

FIG. 1A is an expanded view diagram of a deposition chamber assembly.

FIG. 1B is a diagram of a deposition chamber.

FIG. 2 is a diagram of a deposition chamber.

FIGS. 3A and 3B are perspective and cross section views, respectively, of a substrate holder.

FIG. 4 is a diagram of an input cassette.

FIGS. 5A-5C are diagrams of transferring a substrate holder to a vacuum chamber.

FIGS. 6A-6C are diagrams of transferring a substrate holder onto the carousel.

FIGS. 7A and 7B are front and rear views, respectively, of a confocal molecular beam epitaxy physical vapor deposition system.

FIG. 8 is a flow chart.

### DETAILED DESCRIPTION

We describe here a vacuum deposition system, such as a physical vapor deposition (PVD) system or a chemical vapor deposition system (CVD), that can be operated to rapidly generate a large library of samples, each sample having been processed under a unique set of processing conditions. An assembly in the vacuum deposition chamber of the deposition system holds multiple substrates and allows for control of temperature and deposition parameters on a per-substrate basis. Multiple, small samples can be processed each under individually controlled temperature and deposition conditions, thus facilitating the efficient generation of a library of samples, each having been processed under a distinct set of processing conditions. This system enables the generation of a large number of samples with controlled process variations without human intervention, and enables exploration of the effect of various process parameters on the properties of the resulting materials.

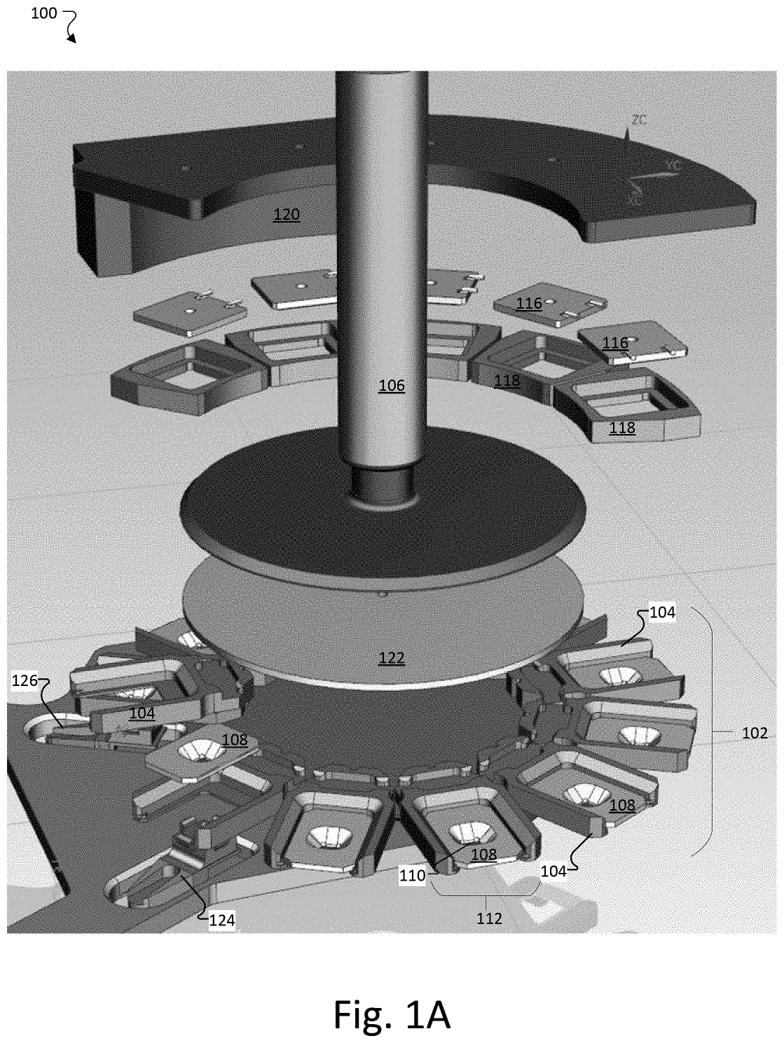

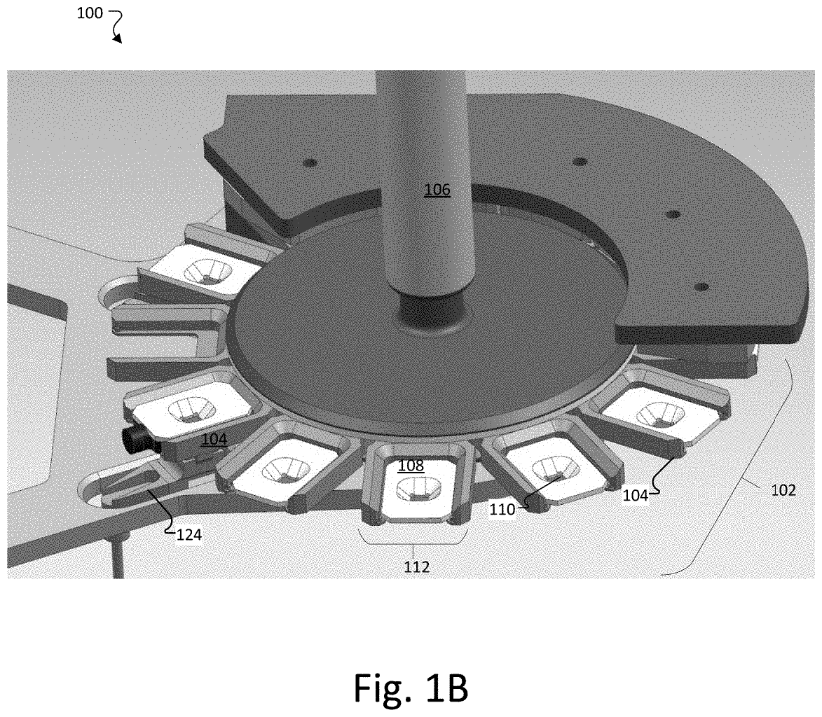

Referring to FIGS. 1A and 1B, a deposition chamber assembly 100 can be positioned in a vacuum chamber of a vacuum deposition system, such as a PVD or CVD system. The deposition chamber assembly 100 enables thermal treatment of and deposition onto multiple substrates, with control over the thermal treatment and deposition on a per-substrate basis such that, in various embodiments, the thermal treatment, the deposition, or both, can be controlled such that each substrate may undergo a thermal treatment, deposition, or both under conditions that are distinct from the conditions of the thermal treatment, deposition, or both of one or more other substrates.

The deposition chamber assembly 100 includes a carousel 102 that has multiple substrate carriers 104 arranged radially in a plane around a central spindle 106. The spindle 106 can rotate, causing rotation of the carousel 102 around the axis defined by the spindle 106.

Each substrate carrier 104 is sized to receive a substrate holder 108 that itself holds one or more substrates 110 (shown in exploded view for clarity). We sometimes refer to a substrate carrier 104 holding a substrate holder 108 with one or more substrates 110 as a substrate assembly 112. The substrate carriers 104 are formed of a rigid, heat-resistant material, such as a ceramic, refractory metals (e.g., tantalum or tungsten), or stainless steel, or another type of heat-resistant material. When the carousel 102 rotates, the substrate assemblies 112 are moved around the interior of the vacuum chamber for sequential exposure to multiple processes, including one or more pre-deposition thermal treatments, one or more deposition processes, and one or more post-deposition thermal treatments. A thermal treatment of a substrate is an exposure by the substrate to a controlled temperature or change in temperature during a set period of time.

Multiple heaters 116 are positioned to each heat a corresponding region of the vacuum chamber, discussed below. In the example of FIGS. 1A and 1B, the heaters 116 are ceramic heaters held in frames 118 positioned above the plane of the substrate carriers 104. In some examples, other types of heaters can be used, such as laser heaters, radiative heaters (e.g., quartz lamps), or heaters formed of graphite or nichrome, or other types of heaters. An insulating plate 120 supports the heaters 116 and acts as a thermal insulator. In some examples, the heaters 116 are fixed in position and do not rotate when the carousel 102 rotates. In some examples, the heaters 116 can be coupled to the carousel 102 or the spindle 106 such that the heaters 116 rotate along with the carousel 102.

A deposition source (not shown) provides material for deposition onto the substrate assemblies 112, e.g., to form thin film coatings on the substrates 110. For instance, the deposition source can be a PVD or CVD source, e.g., a Knudsen cell, an electron beam, a thermal evaporation source, a sublimation source, a plasma gas cracker, a reactive cracker, a gas injector, or another type of source. The deposition source can be positioned to deposit material only onto substrate assemblies located at particular regions of the vacuum chamber, discussed below. In some examples, multiple deposition sources can provide for deposition of multiple materials onto the substrate assemblies 112, e.g., for concurrent or sequential deposition of multiple materials. In some examples, a window between the deposition source and the substrate assemblies can be opened to enable deposition and closed to stop deposition, e.g., to control the timing of a deposition process. For instance, the window can be formed in a wall of the vacuum chamber.

In the configuration of FIGS. 1A and 1B, the deposition source is positioned in a lower portion of the vacuum chamber, below the plane of the substrate carriers 104, such that material is deposited onto the front (downward-facing) surfaces of the substrates 110. A pressure plate 122 is disposed above the plane of the substrate carriers 104. In some examples, e.g., in a differentially pumped system, the pressure plate 122 gives rise to a difference in pressure between an upper portion of the vacuum chamber and the lower portion of the vacuum chamber, facilitating deposition by the deposition source. In some examples, e.g., for plasma-based deposition, the pressure plate 122 can also act as an electrode. In some examples, the pressure plate can include an array of conductive elements such that a different bias can be delivered to each substrate.

Multiple regions are defined in the vacuum chamber, each region corresponding to one or more aspects of processing the substrates, such as input of a substrate into the vacuum chamber, pre-deposition thermal treatment, deposition, post-deposition thermal treatment, and output of a substrate from the vacuum chamber.

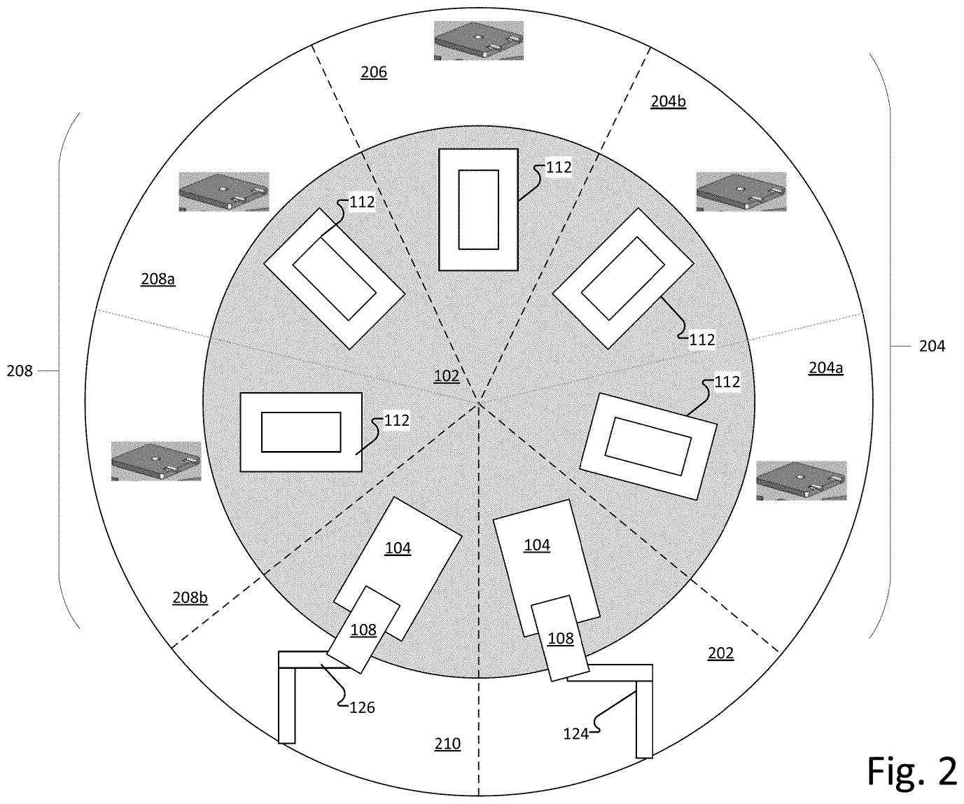

Referring also to FIG. 2, in an input region 202 of the vacuum chamber 200, an input arm 124 of the deposition chamber assembly 100 receives a substrate holder 108 through an input port (not shown) of the vacuum chamber 200 and loads the substrate holder 108 onto the substrate carrier 104 positioned in the input region 202. When the carousel 102 rotates, the substrate carrier 104 with the newly loaded substrate holder 108 is moved into a pre-deposition region 204 of the vacuum chamber 200 and the next substrate carrier 104 is moved into the input region 202 to be loaded with a substrate holder 108.

One or more of the heaters 116 are positioned to heat the substrate assemblies 112 that are located in the pre-deposition region 204. For instance, a first heater 116a can be positioned to heat a substrate assembly 112 that is in a first portion 204a of the pre-deposition region 204 and a second heater 116b can be positioned to heat a substrate assembly 112 that is in a second portion 204b of the pre-deposition region 204.

Each heater 116 is individually controllable separately from each other heater 116. For instance, heater parameters such as a minimum power, a maximum power, a rate of change of power, or other heater parameters can be adjusted on a per-substrate basis. Thus, each substrate assembly 112 can be exposed to a unique thermal treatment in each portion of the pre-deposition region 204.

When the carousel 102 rotates, the substrate assembly 112 in the first portion 204a of the pre-deposition region 204 is moved into the second portion 204b of the pre-deposition region 204 for further pre-deposition thermal treatment. The substrate assembly 112 in the second portion 204b of the pre-deposition region 204 is moved into a deposition region 206. In some examples, the pre-deposition region 204 has only a single portion such that when the carousel 102 rotates, the substrate assembly 112 in the pre-deposition region 204 is moved into the deposition region. In some examples, the pre-deposition region 204 can have more than two portions such that when the carousel rotates, the substrate assemblies 112 in the various portions of the pre-deposition region 204 are moved into the subsequent position, e.g., into the next portion of the pre-deposition region 204 or into the deposition region 206.

In the deposition region 206, material, such as a thin film coating, is deposited onto the substrate 110 held in the substrate assembly 112 that is in the deposition region 206. One or more of the heaters 116 (e.g., a heater 116c) can be positioned to heat the substrate assembly 112 during deposition. The heater 116c is individually controllable separately from each of the other heaters 116.

Deposition parameters for each of the one or more deposition sources can be adjusted on a per-substrate basis such that each substrate 110 can be exposed to a unique set of deposition parameters. Deposition parameters can include composition (e.g., deposition sources used), deposition rate for each of the one or more deposition sources, temperature of each of the one or more deposition sources, deposition power, bias applied to the substrate 110, total deposition time, deposition time for each of the one or more deposition sources, temperature for the substrate, deposition time for the substrate, or other deposition parameters.

When the carousel 102 rotates, the substrate assembly 112 in the deposition region 206 is moved into a post-deposition region 208 for post-deposition thermal treatment. One or more of the heaters 116 are positioned to heat the substrate assemblies 112 that are located in the post-deposition region 208. For instance, a first heater 116d can be positioned to heat the substrate assembly 112 that is in a first portion 208a of the post-deposition region 208 and a second heater 116e can be positioned to heat the substrate assembly 112 that is in a second portion 208b of the post-deposition region 208.

Each heater 116d, 116e in the post-deposition region 208 is individually controllable separately from each other heater 116. For instance, heater parameters such as a minimum power, a maximum power, a rate of change of power, or other heater parameters can be adjusted on a per-substrate basis. Thus, each substrate assembly 112 can be exposed to a unique thermal treatment in each portion of the post-deposition region 204. Examples of post-deposition thermal treatments can include one or more of the following: maintaining a substrate assembly at the deposition temperature for a period of time, annealing a substrate assembly at a higher temperature for a period of time, and subjecting a substrate assembly to a controlled reduction in temperature to a lower, target temperature.

When the carousel 102 rotates, the substrate assembly 112 in the first portion 208a of the post-deposition region 208 is moved into the second portion 208b of the post-deposition region 208 for further post-deposition thermal treatment. The substrate assembly 112 in the second portion 208b of the post-deposition region 208 is moved into an output region 210. In some examples, the post-deposition region 208 has only a single portion such that when the carousel 102 rotates, the substrate assembly 112 in the post-deposition region 208 is moved into the output region 210. In some examples, the post-deposition region 208 can have more than two portions. When the carousel rotates, the substrate assemblies 112 in the various portions of the post-deposition region 208 are moved into the subsequent position, e.g., into the next portion of the post-deposition region 208 or into the output region 210.

In the output region 210 of the vacuum chamber 200, an output arm 126 (FIG. 1) of the deposition chamber assembly 100 unloads the substrate holder 108 from the substrate carrier 104 that is in the output region 210 and removes the substrate holder 108 from the vacuum chamber 200 through an output port (not shown).

In the deposition chamber assembly 100, the rotation of the carousel 102 enables each substrate to be exposed sequentially to one or more pre-deposition thermal treatments, one or more deposition processes, and one or more post-deposition thermal treatments. The ability to individually control each heater on a per-substrate basis allows each substrate to receive thermal treatments that are distinct from the thermal treatments received by one or more other substrates. The ability to control the deposition source on a per-substrate basis similarly allows each substrate to undergo a deposition process under conditions that are distinct from the conditions of the deposition process for one or more other substrates. Each substrate handled by the deposition chamber assembly can thus be processed with an end-to-end set of process conditions, including thermal treatments and deposition, that can be unique to that substrate.

In the example of FIG. 1, a single substrate assembly at a time resides in each region or portion thereof (e.g., each portion of the pre-deposition region 204, the deposition region 206, and each portion of the post-deposition region 206). In some examples, sets of multiple substrate assemblies can be processed concurrently in each region or portion thereof. For instance, two, three, or more than three substrate assemblies can be moved as a set from the first portion 204a to the second portion 204b of the pre-deposition region 204, to the deposition region 206, and to the first portion 208a and second portion 208b of the post-deposition region 208. Processing sets of multiple substrate assemblies will result in multiple substrates having been processed under the same processing conditions, including pre-deposition and post-deposition thermal treatments and deposition process parameters. Multiple, identically processed substrates can be useful, e.g., to supply samples for extensive downstream testing where only a single substrate may not be sufficient.

The heaters 116 can be controlled by an automated control system that controls heater parameters such as the heater power, the rate of change of the heater power, or other heater parameters. In some examples, the control system can be a closed loop control system that controls the heaters 116 based on in situ temperature measurements. For instance, a pyrometer can be used to measure the temperature of the back (upward-facing) surface of each substrate 110, and the heater parameters can be controlled by the closed loop control system to achieve a target substrate temperature. In some cases, the temperature of the substrate holders 108 or substrate carriers 104 can be measured and used as a proxy for the substrate temperature. In some examples, additional measurements, such as in situ film thickness or uniformity measurements, can also be used as inputs to the closed loop control system.

In the example of FIG. 1, the heaters 116 are fixed in position relative to the carousel 102 and do not rotate when the carousel 102 rotates. In this configuration, each heater 116 heats a corresponding region of the vacuum chamber 200, and thus heats the substrate assemblies 112 that rotate into that region of the vacuum chamber. In some examples, the heaters 116 are coupled to the spindle 106 such that the heaters 106 also rotate along with the carousel 102. In this configuration, the position of the heaters 116 is fixed relative to the substrate assemblies 112 and a single heater heats the same one or more one or more substrate assemblies 112 for all of the processes in the vacuum chamber, including the pre-deposition thermal treatment, the deposition process, and the post-deposition thermal treatment.

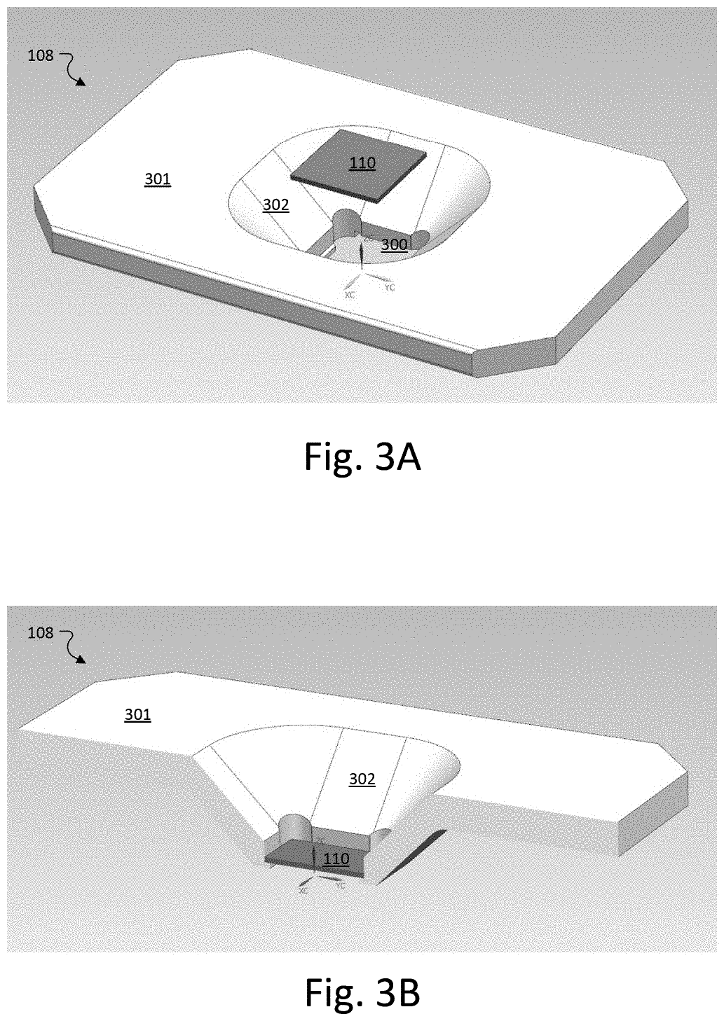

Referring to FIGS. 3A and 3B, a substrate holder 108 configured to hold a single substrate 110 (as shown) or multiple substrates includes a base 301 with a recess 300 formed therein. The substrates 110 can be any material capable of withstanding a vacuum deposition process, such as silicon, silicon oxides, metal oxides (e.g., sapphire), or other materials. The substrate holder 108 can be made of a rigid, heat resistant material, such as a ceramic. In some examples, the substrate 110 is placed into the recess 300 in the substrate holder 108 with the front surface 300 facing down such that material can be deposited onto the front surface 300 from a deposition source positioned in the lower portion of the vacuum chamber (as in the example of FIG. 1).

The recess 300 in the substrate holder 108 is defined by a top opening, a bottom opening, and side walls 302. One or more of the side walls 302 can be inclined at an angle to the top surface of the substrate holder 108. For instance, the side walls can be inclined at an angle θ of about 35°, about 40°, about 45°, about 50°, about 55°, about 60°, or another angle. The inclined side walls 302 of the recess 300 can help facilitate in situ metrology access to the substrate 110, e.g., for optical measurements of the thickness of the deposited coating (e.g., grazing incidence optical metrology).

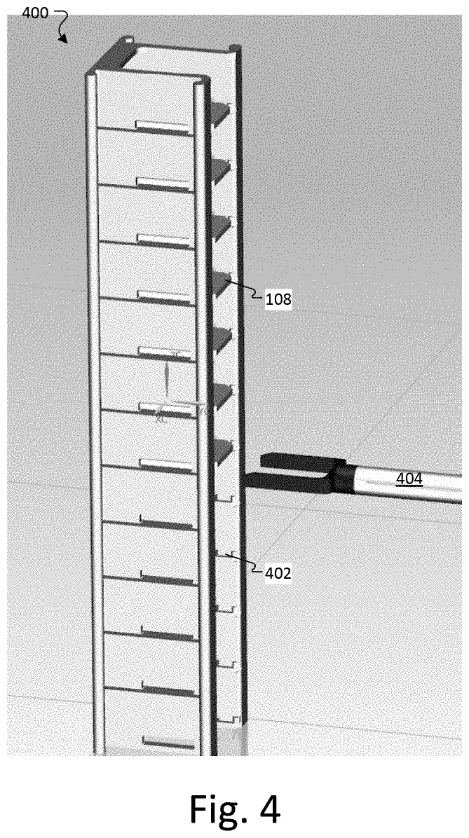

Referring to FIGS. 4-6, an automated, robotic loading process can be used to load multiple substrate holders 108 sequentially into the vacuum chamber of the vacuum deposition system. Referring specifically to FIG. 4, an input cassette 400 stores multiple substrate holders 108 each having a substrate held therein. Each substrate holder 108 rests on a corresponding ledge 402 of the cassette. The substrate holders 108 stored in the input cassette 400 can be transferred, one at a time, to corresponding substrate carriers 104 (FIG. 1) of the deposition chamber assembly 100 by a robotic transfer arm 404. The transfer arm 404 is configured for horizontal motion and can be driven by an actuator, such as a magnetically coupled linear actuator. In some examples, the input cassette 400 can be held under vacuum to facilitate transfer of the substrate holders 108 into the vacuum chamber.

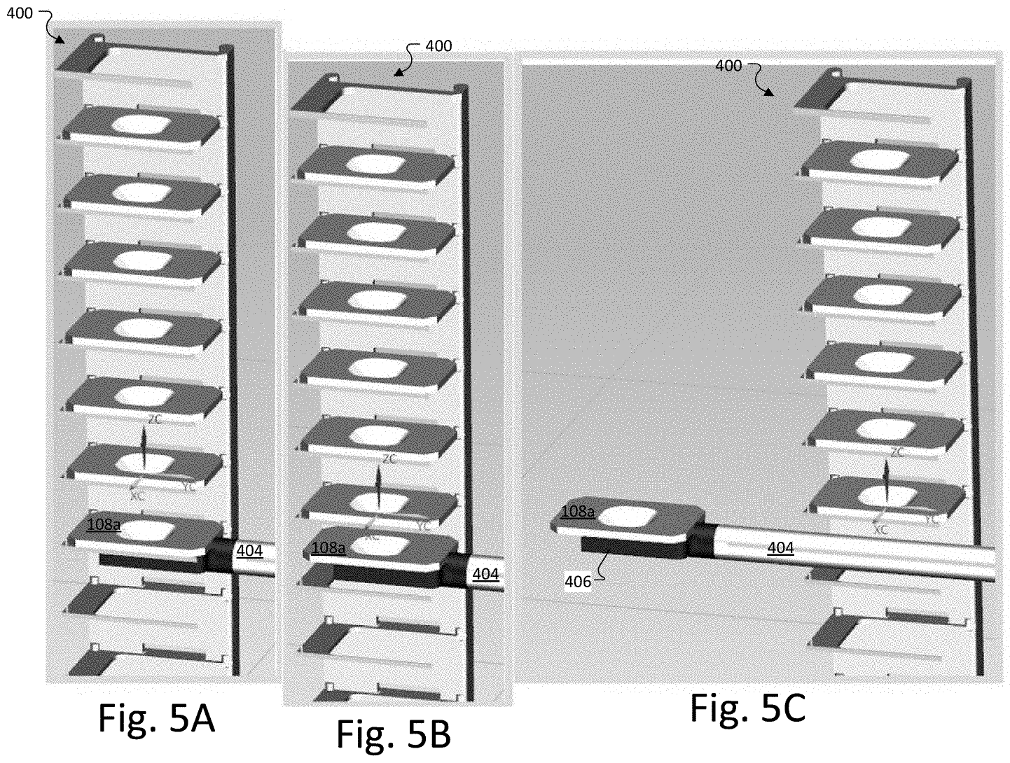

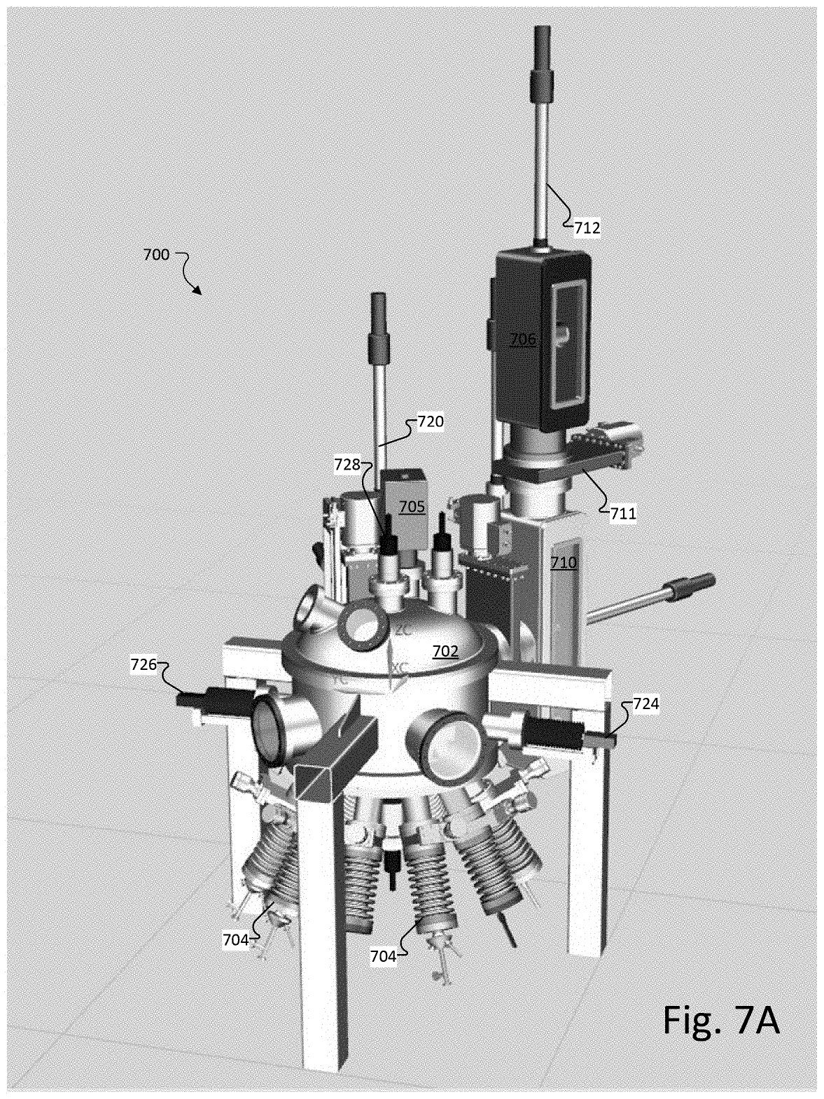

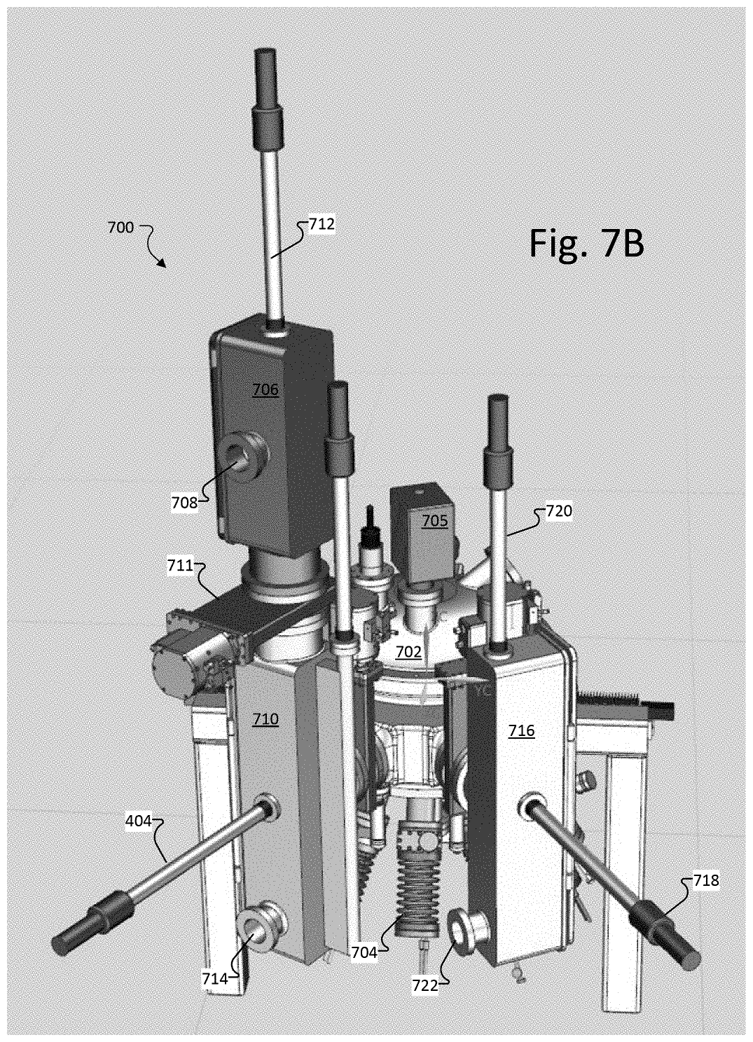

FIGS. 5A-5C depict a process for transferring a particular substrate holder 108a from the input cassette 400 to a vacuum chamber. The transfer arm 404 advances into the input cassette 400 between a ledge on which the substrate holder 108a rests and the next ledge below the substrate holder 108a. The advance stops when a transfer fork 406 of the transfer arm 404 is aligned under the substrate holder 108a (FIG. 5A). When the transfer fork 406 is in alignment, the cassette 400 shifts downward until the substrate holder 108a rests on the transfer fork 406 (FIG. 5B). For instance, the vertical motion of the cassette 400 can be driven by an actuator, such as a magnetically coupled linear actuator 712 (see FIG. 7A). In some examples, the transfer fork 406 can be magnetic and the substrate holder 108a can include a magnet, e.g., an embedded magnet or a magnet affixed to the surface of the substrate holder 108a, to provide stability when the substrate holder 108a is carried into the vacuum chamber 200 by the transfer fork 406. The transfer arm 404, with the substrate holder 108a carried on the transfer fork 406, advances forward into the vacuum chamber (FIG. 5C). In some examples, there is a door (not shown) between the input cassette 400 and the vacuum chamber that is opened as the transfer arm 404 advances toward the vacuum chamber.

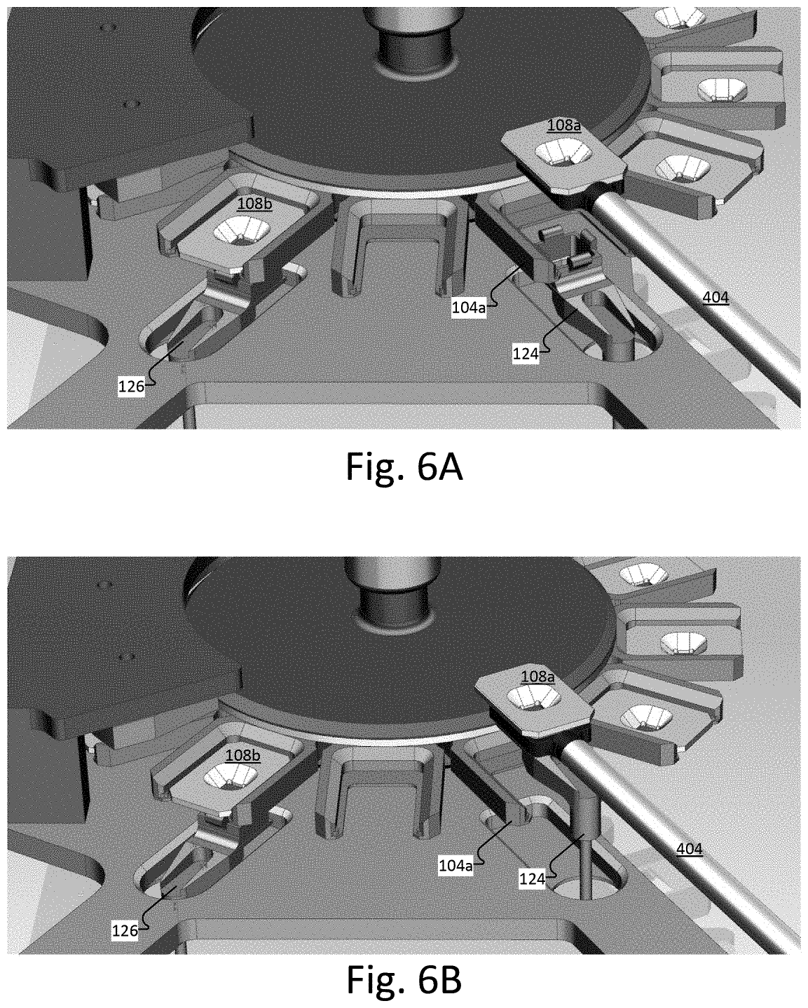

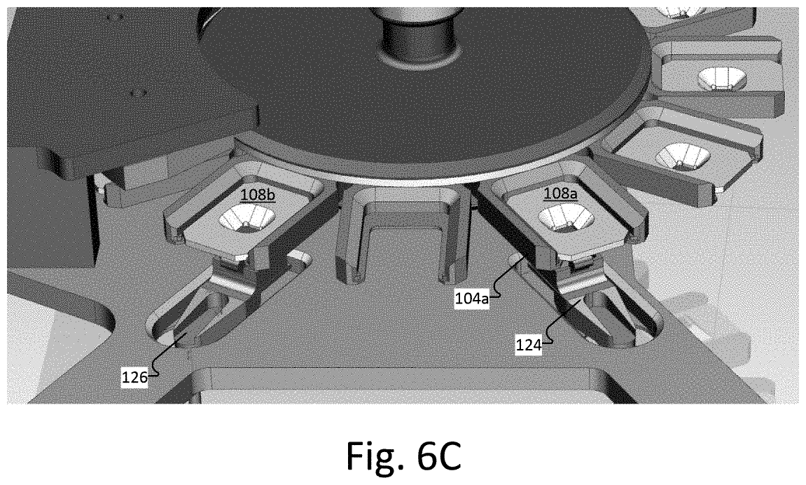

FIGS. 6A-6C depict a process for transferring the particular substrate holder 108a onto an empty substrate carrier 104a of the carousel 102 in a vacuum chamber. The transfer arm 404 continues to advance into the vacuum chamber until the substrate holder 108a is aligned above the substrate carrier 104a (FIG. 6A). The input arm 124 rises up to contact the substrate holder 108a (FIG. 6B). The transfer arm 404 withdraws from the vacuum chamber, leaving the substrate holder 108a resting on the input arm 124. The input arm 124 can be configured for vertical motion and can be driven by an actuator. The input arm 124 then lowers the substrate holder 108a into the empty substrate carrier 104a (FIG. 6C).

Still referring to FIG. 6C, to transfer a particular substrate holder 108b out of the vacuum chamber, the output arm 126 raises the substrate holder 108b to an appropriate height for collection by an output transfer arm. For instance, the output transfer arm can have a structure similar to that of the transfer arm 404 used for transfer of substrate holders into the vacuum chamber 200. The output transfer arm advances into the vacuum chamber 200 and advances until the substrate holder 108b rests on the transfer fork of the output transfer arm. The output arm 126 is lowered and the output transfer arm, carrying the substrate holder 108b, is withdrawn from the vacuum chamber. Once withdrawn from the vacuum chamber, the substrate holder 108b can be shelved in an output cassette. For instance, the output cassette can have a structure similar to that of the input cassette 400.

In some examples, the transfer arm 404 and the output transfer arm can be configured to move both horizontally and vertically, such that the transfer arms themselves can lower substrate holders onto corresponding substrate carriers and can raise substrate holders up from corresponding substrate carriers, respectively.

FIGS. 7A and 7B are diagrams of an example confocal molecular beam epitaxy (MBE) PVD system 700 with a vacuum chamber 702 in which the deposition chamber assembly 100 of FIG. 1 is installed. Multiple plasma sources 704 provide material for deposition onto substrates in the vacuum chamber 702. In some examples, the plasma sources 704 can be pointed directly at the expected location of the substrates in the deposition zone of the vacuum chamber. In some examples, the plasma sources 704 can be tilted relative to the expected location of the substrates, e.g., to achieve off-axis deposition effects.

A motor 705 drives rotation of the central spindle of the deposition chamber assembly (e.g., the spindle 106 of FIG. 1). For instance, the motor can be magnetically coupled to the spindle. Operating the motor thus drives rotation of the carousel such that the substrate assemblies carried on the carousel can receive individualized pre-deposition thermal treatment, deposition processing, and post-deposition thermal treatment.

An input cassette (e.g., the input cassette 400 of FIG. 4) is placed in a bake out chamber 706 for entry into the vacuum system. In the bake out chamber 706, the input cassette is pumped down to a first vacuum level with vacuum applied from a vacuum port 708. Once baked as appropriate, an isolation valve 711 is opened through which the input cassette is transferred from the bake out chamber 706 to a cassette elevator 710. Vertical motion of the input cassette from the bake out chamber 706 to the cassette elevator 710 is driven by an input actuator 712, such as a linear actuator, e.g., a magnetically coupled linear actuator. In the cassette elevator 710, the input cassette can be pumped down to a second vacuum level, e.g., to the pressure of the vacuum chamber 702, with vacuum applied from a vacuum port 714. Once the input cassette is in the cassette elevator 710, the substrate holders can be transferred individually into the vacuum chamber 702 by the transfer arm 404, e.g., as shown in FIGS. 4-6. The vertical motion of the input cassette to rest a substrate holder on the fork of the transfer arm 404 (e.g., as shown in FIG. 5B) can be controlled by the input actuator 712.

An output cassette is disposed in an output cassette elevator 716 and receives substrate holders withdrawn from the vacuum chamber 712 by an output transfer arm 718. Vertical motion of the output cassette is controlled by an output actuator 720, such as a linear actuator, e.g., a magnetically coupled linear actuator. A vacuum port 722 enables the output cassette elevator 716 to be pumped down to a desired vacuum level, e.g., the pressure of the vacuum chamber 702.

During deposition in the vacuum chamber, the thermal treatment, deposition parameters, or both, can be adjusted on a per-substrate basis. For instance, for the MBE PVD system 700, parameters such as the temperature, vapor pressure, mass flow rate of gas from the sources 704, or other parameters can be adjusted on a per-substrate basis.

The vacuum chamber 702 can be equipped with one or more metrology tools, such as a laser source 724 and an optical detector 726 for laser metrology, e.g., grazing incidence optical metrology of film thickness; an ellipsometry tool; a reflection high-energy electron diffraction (RHEED) tool; or another metrology tool. The vacuum chamber 702 can be equipped with temperature sensors, such as infrared temperature sensors 728, to measure the temperature of the substrates or of other components in the interior of the vacuum chamber 702.

In some examples, a sputtering deposition process can be controlled on a per-substrate basis. For instance, deposition parameters that can be adjusted on a per-substrate basis include a bias between the substrate and a sputtering source, a type of bias (e.g., radio frequency (RF), direct current (DC), or both), a plasma power, a gas flow rate into the plasma source, or other sputtering deposition parameters. In some examples, reactive gas, such as oxygen or ammonia, can be injected near the substrate; the injection of reactive gas and injection parameters such as a mass flow rate of the reactive gas, a timing of the reactive gas injection, or an identity of the reactive gas, or other parameters can be controlled on a per-substrate basis.

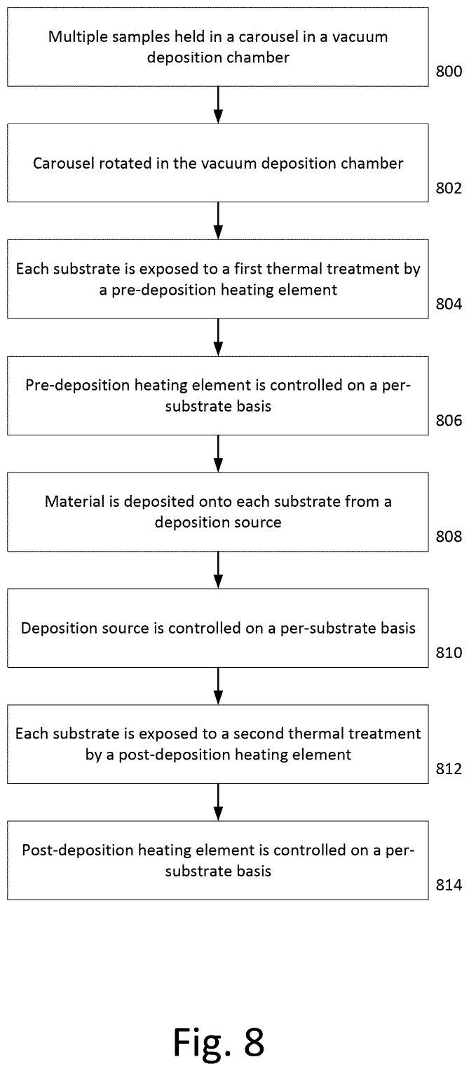

Referring to FIG. 8, in a general process, multiple samples are held in a carousel disposed in a vacuum deposition chamber (800). The carousel is rotated in the vacuum deposition chamber (802).

Each substrate is exposed, one after the other, in a first region of the vacuum deposition chamber to a first thermal treatment by a pre-deposition heating element (804). The pre-deposition heating element can be controlled on a per-substrate basis (806), such that each substrate receives a pre-deposition thermal treatment that can be distinct from the thermal treatment of one or more other substrates. For instance, one or more of a maximum power, a minimum power, and a rate of power change of the pre-deposition heating element can be adjusted to control the temperature of the substrate. Exposing a substrate to the first thermal treatment can include exposing the substrate to multiple, sequential thermal treatments, each by a distinct one of multiple pre-deposition heating elements. Each of the multiple pre-deposition heating elements can be controlled separately from each other of the multiple pre-deposition heating elements.

In a second region of the vacuum deposition chamber, material is deposited from a deposition source onto a surface of each substrate (808), one after the other, e.g., by a physical vapor deposition process. The deposition source can be controlled on a per-substrate basis (810), such that material is deposited onto each substrate under conditions that can be distinct from the conditions of the deposition onto one or more other substrates. For instance, one or more of the deposition rate, the temperature of the deposition source, the power, the bias applied to the substrate, and the deposition time can be controlled. Controlling the deposition source can include selecting one or more deposition sources from multiple deposition sources for deposition of material onto a particular substrate.

In a third region of the vacuum deposition chamber, the substrate is exposed to a second thermal treatment by a post-deposition heating element (812). The post-deposition heating element can be controlled on a per-substrate basis (814), such that each substrate receives a post-deposition thermal treatment that can be distinct from the thermal treatment of one or more other substrates. For instance, one or more of a maximum power, a minimum power, and a rate of power change of the post-deposition heating element can be adjusted. Exposing a substrate to the first thermal treatment can include exposing the substrate to multiple, sequential thermal treatments, each by a distinct one of multiple post-deposition heating elements. Each of the multiple post-deposition heating elements can be controlled separately from each other of the multiple post-deposition heating elements. In some examples, the substrate can be actively cooled in the third region of the vacuum deposition chamber to control the temperature of the substrate.

A number of embodiments have been described. Nevertheless, it will be understood that various modifications may be made without departing from the spirit and scope of the invention. For example, some of the steps described above may be order independent, and thus can be performed in an order different from that described.

Other implementations are also within the scope of the following claims.

What is claimed is:

1. A vacuum deposition system comprising:
a vacuum deposition chamber having multiple regions defined therein;
a carousel disposed in the vacuum deposition chamber, the carousel configured to hold multiple substrates, the carousel rotatable around a central spindle;
a deposition source positioned to deposit material onto a substrate located in a deposition region of the vacuum deposition chamber; and
multiple heating elements disposed in the vacuum deposition chamber in a fixed position relative to the central spindle, each heating element being controllable separately from each other heating element, wherein each heating element is positioned to apply heat to a corresponding region of the vacuum deposition chamber.

2. The vacuum deposition system of claim 1, wherein the carousel comprises multiple substrate carriers each configured to hold a corresponding substrate.

3. The vacuum deposition system of claim 2, wherein in response to a rotation of the carousel, the substrate carriers are moved from (1) a first position in which each substrate carrier is located in a corresponding first region of the vacuum deposition chamber to (2) a second position in which each substrate carrier is located in a corresponding second region of the vacuum deposition chamber.

4. The vacuum deposition system of claim 3, wherein at least one of the multiple heating elements is a pre-deposition heating element positioned such that in response to the rotation of the carousel, the substrate carrier in the region corresponding to the pre-deposition heating element is moved to the deposition region.

5. The vacuum deposition system of claim 3, wherein at least one of the multiple heating elements is a post-deposition heating element positioned such that in response to the rotation of the carousel, the substrate carrier in the deposition region is moved into the region corresponding to the post-deposition heating element.

6. The vacuum deposition system of claim 2, wherein each substrate carrier is sized to receive a substrate holder holding the corresponding substrate.

7. The vacuum deposition system of claim 6, wherein each substrate holder includes a base with a recess formed therein, the recess being sized to hold the substrate.

8. The vacuum deposition system of claim 7, wherein walls defining the recess of each substrate holder are inclined at an angle of less than 90° to a surface of the base.

9. The vacuum deposition system of claim 1, wherein the multiple heating elements comprise ceramic heaters.

10. The vacuum deposition system of claim 1, wherein the multiple heating elements comprise laser heaters.

11. The vacuum deposition system of claim 1, comprising a control system configured to control each heating element separately from each other heating element.

12. The vacuum deposition system of claim 11, wherein the control system comprises a closed loop control system.

13. The vacuum deposition system of claim 12, wherein the closed loop control system is configured to control each heating element based on a temperature measured in the corresponding region of the vacuum deposition chamber.

14. The vacuum deposition system of claim 1, further comprising multiple pyrometers, each pyrometer configured to measure a temperature of one or more of (1) a substrate, (2) a substrate holder holding a substrate, and (3) a substrate carrier in a corresponding region of the vacuum deposition chamber.

15. The vacuum deposition system of claim 1, further comprising an input assembly for automated loading of a substrate into the vacuum deposition chamber.

16. The vacuum deposition system of claim 15, wherein the input assembly comprises:
an input arm disposed in the vacuum deposition chamber, the input arm configured for vertical movement; and
a transfer arm configured for horizontal movement into the vacuum deposition chamber.

17. The vacuum deposition system of claim 1, wherein the vacuum deposition chamber comprises a physical vapor deposition chamber.

18. The vacuum deposition system of claim 1, wherein the vacuum deposition chamber comprises a chemical vapor deposition chamber.

19. An apparatus comprising:
a carousel for a vacuum deposition chamber, the carousel having multiple substrate carriers arranged radially around a central spindle, each substrate carrier configured to hold a substrate, wherein the carousel is rotatable around the central spindle;
multiple heating elements disposed in the vacuum deposition chamber above the substrate carriers, each heating element being controllable separately from each other heating element, wherein the heating elements are fixed in position relative to the central spindle;
an input arm configured to transfer a substrate input into the vacuum deposition chamber onto a substrate carrier, the input arm configured for vertical motion; and
an output arm configured to transfer a substrate from a substrate carrier to an output mechanism, the output arm configured for vertical motion.

20. A method comprising:
holding multiple substrates in a carousel disposed in a vacuum deposition chamber;
rotating the carousel in the vacuum deposition chamber, including, for each of the multiple substrates:
in a first region of the vacuum deposition chamber, exposing the substrate to a first thermal treatment by a pre-deposition heating element;
in a second region of the vacuum deposition chamber, depositing a material from a deposition source onto a surface of the substrate; and
in a third region of the vacuum deposition chamber, exposing the substrate to a second thermal treatment by a post-deposition heating element; and
controlling one or more of the pre-deposition heating element, the deposition source, and the post-deposition heating element on a per-substrate basis.

21. The method of claim 20, wherein controlling the pre-deposition heating element or the post-deposition heating element comprises adjusting one or more of a maximum power, a minimum power, and a rate of power change.

22. The method of claim 20, wherein controlling the deposition source comprises controlling one or more of a deposition rate, a temperature of the deposition source, a power, a bias applied to the substrate, and a deposition time.

23. The method of claim 20, wherein controlling the deposition source comprises selecting one or more of multiple deposition sources.

24. The method of claim 20, wherein exposing each substrate to the first thermal treatment comprises exposing each substrate to multiple, sequential thermal treatments, each of the sequential thermal treatments by a corresponding one of multiple pre-deposition heating elements.

25. The method of claim 24, comprising controlling each of the multiple pre-deposition heating elements separately from each other of the multiple pre-deposition heating elements.

26. The method of claim 20, further comprising controlling one or more of the pre-deposition heating element and the post-deposition heating element by a closed loop control system.

27. The method of claim 20, further comprising measuring a temperature in one or more of the first region and the third region of the vacuum deposition chamber.

28. The method of claim 27, further comprising one or more of controlling the pre-deposition heating element based on the temperature measured in the first region and controlling the post-deposition heating element based on the temperature measured in the second region.

29. The method of claim 20, further comprising measuring one or more of a thickness and a uniformity of the material deposited onto the surface of each substrate.

30. The method of claim 20, wherein depositing a material comprises depositing the material by a physical vapor deposition process.

31. The method of claim 20, wherein depositing a material comprises depositing the material by a chemical vapor deposition process.

32. The method of claim 20, further comprising transferring a substrate from an input cassette elevator to the carousel.

33. The method of claim 32, wherein transferring a substrate from the input cassette elevator to the carousel comprises:
retrieving the substrate from a cassette in the input cassette elevator with a transfer arm;
advancing the transfer arm into the vacuum deposition chamber;
transferring the substrate from the transfer arm to an input arm disposed in the vacuum deposition chamber; and
actuating the input arm to dispose the substrate on the carousel.

34. The method of claim 33, wherein retrieving the substrate from the cassette includes:
advancing the transfer arm into the cassette in a space below the substrate; and
actuating a downward motion of the input cassette elevator to dispose the substrate on the transfer arm.

35. The method of claim 20, further comprising transferring a substrate from the carousel to an output cassette elevator.
